(19) United States
(12) Patent Application Publication
(10) Pub. No.: US 2012/0319104 A1
(43) Pub. Date: Dec. 20, 2012

(54) METHOD FOR PRODUCING CIRCUIT BOARD, CIRCUIT BOARD AND DISPLAY DEVICE

(75) Inventors: Yoshihito Hara, Osaka-shi (JP); Yukinobu Nakata, Osaka-shi (JP)

(73) Assignee: SHARP KABUSHIKI KAISHA, Osaka-shi, Osaka (JP)

(21) Appl. No.: 13/579,286

(22) PCT Filed: Nov. 4, 2010
(86) PCT No.: PCT/JP2010/069601

§ 371 Date: Aug. 16, 2012

(30) Foreign Application Priority Data
Feb. 23, 2010 (JP) 2010-037554

(51) Int. Cl. H01L 29/26; H01L 21/34

(52) U.S. Cl. 257/43; 438/104; 257/E29.079; 257/E21.459

(57) ABSTRACT

Provided is a method of producing a circuit board of which the aperture ratio is increased. The method of producing a circuit board of the present invention is a method of producing a circuit board that includes a thin film transistor, the thin film transistor including an oxide semiconductor layer, the method including steps of: forming the oxide semiconductor layer; and converting the oxide semiconductor layer into a conductive form.

### TECHNICAL FIELD

The present invention relates to a method of producing a circuit board, a circuit board, and a display device. Particularly, the present invention relates to a method of producing a circuit board which is to be used as a component member of an electronic apparatus such as a display device, a circuit board, and a display device.

### BACKGROUND ART

A circuit board includes an electronic circuit as a component. For example, a circuit board that includes elements such as thin film transistors (TFTs) is widely used as a component member of an electronic apparatus such as a liquid crystal display device, an organic electroluminescence display device, and a solar cell.

Hereinafter, a circuit configuration of a TFT array board, which constitutes a TFT-driving liquid crystal display panel, will be described as an example. In general, the TFT array board includes a pixel circuit having a structure where TFTs as switching elements are disposed at intersections in an m×n matrix wire lines formed by m-row scan lines and n-column signal lines. In addition, a drain wire line of the TFT is connected to an electrode of a picture element. Peripheral circuits such as a scan driver IC or a data driver IC are connected to gate wire lines and source wire lines of the TFTs, respectively.

The circuit is influenced by performance of TFTs constructed on the TFT board. In other words, since the performance of TFTs constructed on the TFT board varies depending on the qualities of materials of the TFT, the circuit constructed on the TFT board affects operability of the circuit by the TFT constructed on the circuit board, the size of the circuit, producibility, or the like. In a conventional circuit board, a-Si (amorphous silicon) is widely employed in terms of low cost and easiness in production.

Other semiconductor compounds used for a TFT channel layer are also disclosed. Patent Literature 1, for example, discloses a thin film transistor with the channel layer formed of an oxide semiconductor that includes one of elements selected from In, Ga, and Zn.

### CITATION LIST

### Patent Literature

Patent Literature 1: JP 2008-277326 A

### SUMMARY OF INVENTION

### Technical Problem

FIG. 16 illustrates a schematic plan view to illustrate a picture element of a circuit board that is produced using a conventional a-Si TFT.

In a conventional circuit board using an a-Si TFT, the transmittance may not be sufficiently increased because the area of TFT 141 is large. This is because (1) a-Si does not have a sufficiently high mobility, and (2) on the design of an a-Si TFT, the size of the a-Si TFT becomes large to some extent since large Cs capacitance is employed in order to follow a change in Cgd capacitance due to alignment accuracy. There has thus been room for using more appropriate TFTs regarding an improvement of the aperture ratio.

The inventors have taken into consideration the aforementioned problems to make the present invention. Thus, the present invention has an object to provide a method of producing a circuit board having an increased aperture ratio.

### Solution to Problem

The inventors have researched various methods of producing a circuit board having an increased aperture ratio and focused on conversion of an oxide semiconductor layer into a conductive form in a method of producing a circuit board of which the semiconductor layer is composed of an oxide semiconductor. Then, the inventors have found out that sufficient electrical connection (source→TFT→drain→electrode of a picture element) can be established between the source and the drain by only using the oxide semiconductor in which the oxide semiconductor layer is converted into a conductive form. The inventors have also found out that the aperture ratio can be increased by using an oxide semiconductor having high mobility, which can reduce the size of TFTs in the TFT portion of the circuit board. Accordingly, they have conceived an idea to beautifully solve the aforementioned problem, and thus, arrive at the present invention.

According to an aspect of the invention, provided is a method of producing a circuit board that carries a thin film transistor, the thin film transistor including an oxide semiconductor layer, the method including the steps of forming the oxide semiconductor layer; and converting the oxide semiconductor layer into a conductive form.

The method of producing the circuit board according to the present invention utilizes, in place of a-Si, an oxide semiconductor, which has an advantage of high mobility. In addition, the method includes a process of converting the oxide semiconductor into a conductive form. Thus, the oxide semiconductor, which has high mobility, achieves reduction in the TFT area, which may not be achieved in a conventional technique using a-Si, to thereby increase the aperture ratio.

The configuration of the circuit board of the present invention is not especially limited by other components as long as it essentially includes such components.

Hereinafter, preferable embodiments of a circuit board according to the present invention will be described in detail.

According to another aspect of the invention, provided is a circuit board obtainable by the method of producing the circuit board according to the present invention. The circuit board of the invention enables to exert the same effect of increasing the aperture ratio as described above.

According to a further aspect of the invention, provided is a circuit board that carries a thin film transistor, the thin film transistor including an oxide semiconductor layer, wherein the oxide semiconductor layer includes a portion of which the surface is converted into a conductive form and a portion of a semiconductor layer. Such configuration enables to sufficiently convert lead portions of picture elements into a conductive form while maintaining the switching function of the TFT. The oxide semiconductor layer is preferably an amorphous oxide semiconductor layer in terms of easiness in production of the portion to be converted into a conductive form and the portion of the semiconductor. Among them, in a preferred embodiment of the circuit board according to the present invention, the oxide semiconductor layer is made of an indium-gallium-zinc complex oxide.

In a preferred embodiment of the circuit board according to the present invention, the circuit board is configured so that a lower layer of the oxide semiconductor layer is formed of an insulating film, and an upper layer of a conductive portion of the oxide semiconductor layer is formed of an insulating film. In other words, in the above embodiment, the lower layer downward from the conductive portion of the oxide semiconductor is formed of only the insulating film, and the portion between the conductive portion of the oxide semiconductor and the electrode of a picture element or the liquid crystal layer is formed of only the insulating film except the electrode of a picture element. In this manner, the electrical connection can be formed between the source and the drain in only the semitransparent oxide semiconductor layer and the conductive portion, whereby further increase of the aperture ratio can be achieved.

In a preferred embodiment of the circuit board according to the present invention, the circuit board is configured so that a drain formed of a source metal and a gate wire line do not overlap each other in a thin film transistor element portion (in a TFT portion) as the principal surface of the board is seen in a plan view. In the invention, the source wire line and the drain that is formed of a source metal can be disposed to be separated from each other since sufficient electrical connection can be formed using only the oxide semiconductor. Thus, the drain formed of a source metal can be disposed to be separated from the gate wire line, whereby an alignment-free (Cgd alignment-free) form can be achieved. Large Cs capacitance may not be employed, and therefore, the area of Cs can be reduced, whereby the aperture ratio can be increased.

In a preferred embodiment of the circuit board according to the present invention, the oxide semiconductor layer includes a portion of which the resistivity is equal to or higher than 10² μΩ·cm but equal to or lower than 10⁸ μΩ·cm. This embodiment enables, while maintaining the switching function of the TFT, to downsize the TFT by using a semiconductor material having high mobility, whereby the aperture ratio can be increased. In a preferred embodiment of the circuit board according to the present invention, the oxide semiconductor layer further includes a portion of which the resistivity is higher than 10⁸ μΩ·cm.

In a preferred mode of the circuit board according to the present invention, the circuit board includes a portion where the thin film transistor element and a light-shielding layer do not overlap each other as the principal surface of the board is seen in a plan view. In an a-Si TFT, light leakage occurs in the transistor, and Vth shifting occurs in terms of reliability. Due to the optical property, OFF leakage (leakage current during the standby period of TFT) occurs, and it is generally necessary to shield the TFT with the BM or the like. The circuit board according to the present invention is configured to include a portion where the thin film transistor element and the light-shielding layer do not overlap each other, and it is thus possible to further increase the aperture ratio of the circuit board. For example, when the circuit board includes two or more thin film transistor elements that are disposed in serious per electrode of a picture element, OFF resistance of the TFT can be sufficiently reduced. As a result, it is possible to sufficiently drive the TFT without light shielding by using the black matrix (BM). The above expression “include (s) a portion where the thin film transistor element and the light-shielding layer do not overlap each other” denotes that there is a portion where the overlapping is not formed to a degree that the effect of increasing the aperture ratio, which can be achieved by the present invention, may be obtained. In a more preferable embodiment, the thin film transistor element and the light-shielding layer do not substantially overlap each other as the principal surface of the board is seen in a plan view.

The circuit board according to the present invention may be a circuit board capable of obtaining the effect of increasing the aperture ratio by at least one of:

(1) reduction in TFT area due to an oxide semiconductor having high mobility;

(2) reduction in the area of Cs by Cgd alignment-free configuration; and

(3) TFT not shielded by BM.

According to an aspect of the present invention, provided is a display device which includes the circuit board according to the present invention. Examples of such a display device include a liquid crystal display device, an EL display device such as an organic EL display device or an inorganic EL display device, or the like.

The preferred embodiment of the display device according to the present invention is the same as the preferred embodiment of the circuit board according the present invention described above.

The aforementioned modes may be employed in appropriate combination as long as the combination is not beyond the spirit of the present invention.

### Advantageous Effects of Invention

According to the present invention, it is possible to sufficiently increase an aperture ratio of a circuit board that carries TFTs, which include an oxide semiconductor layer.

### BRIEF DESCRIPTION OF DRAWINGS

FIG. 1 is a schematic plan view to illustrate a picture element in a circuit board according to an embodiment.

FIG. 2 is a view to illustrate a step of conversion of an oxide semiconductor layer into a conductive form according to an embodiment.

FIG. 3 is a schematic cross-sectional view of a TFT portion in the circuit board according to an embodiment.

FIG. 4 is a schematic cross-sectional view to illustrate a board where gate wire lines are formed in a method of producing the circuit board according to an embodiment.

FIG. 5 is a schematic cross-sectional view to illustrate the board obtained through a process that includes the steps of forming an oxide semiconductor layer, arranging ES (etching stopper), and performing plasma treatment on the oxide semiconductor layer in the method of producing the circuit board according to an embodiment.

FIG. 6 is a schematic cross-sectional view to illustrate the board obtained through etching on the oxide semiconductor layer in the method of producing the circuit board according to an embodiment.

FIG. 7 is a schematic cross-sectional view to illustrate the board obtained through formation of a source wire line and a drain in the method of producing the circuit board according to an embodiment.

FIG. 8 is a schematic cross-sectional view to illustrate the board where an organic insulating film is formed in the method of producing the circuit board according to an embodiment.

FIG. 9 is a schematic cross-sectional view to illustrate the board where an electrode of a picture element is formed in the method of producing the circuit board according to an embodiment.

FIG. 10 is a schematic plan view to illustrate picture elements in a circuit board that includes one TFT per picture element as a modified example of an embodiment.

FIG. 11 is a schematic plan view to illustrate picture elements in a circuit board that includes two TFTs per picture element as a modified example of an embodiment.

FIG. 12 is a schematic plan view to illustrate picture elements in a circuit board that includes three TFTs per picture element as a modified example of an embodiment.

FIG. 13 is a schematic plan view to illustrate the circuit board according to the embodiment.

FIG. 14 is a schematic exploded perspective view to illustrate a structure of a liquid crystal panel according to an embodiment.

FIG. 15 is a schematic exploded perspective view to illustrate a structure of a liquid crystal display device that includes the liquid crystal panel illustrated in FIG. 14.

FIG. 16 is a schematic plan view to illustrate a picture element of a circuit board that is produced using a conventional a-Si TFT.

### DESCRIPTION OF EMBODIMENTS

In this text, a drain, a source wire line, and a gate wire line include a drain electrode, a source electrode, and a gate electrode of a TFT as portions thereof, respectively.

A circuit board is a board where TFTs are installed in an embodiment, which is also called a TFT-side board. A board facing the circuit board is a board where a color filter (CF) is installed in the embodiment, which is also called a CF-side board.

The present invention will be mentioned in more detail referring to the drawings in the following embodiments, but is not limited to these embodiments.

### First Embodiment

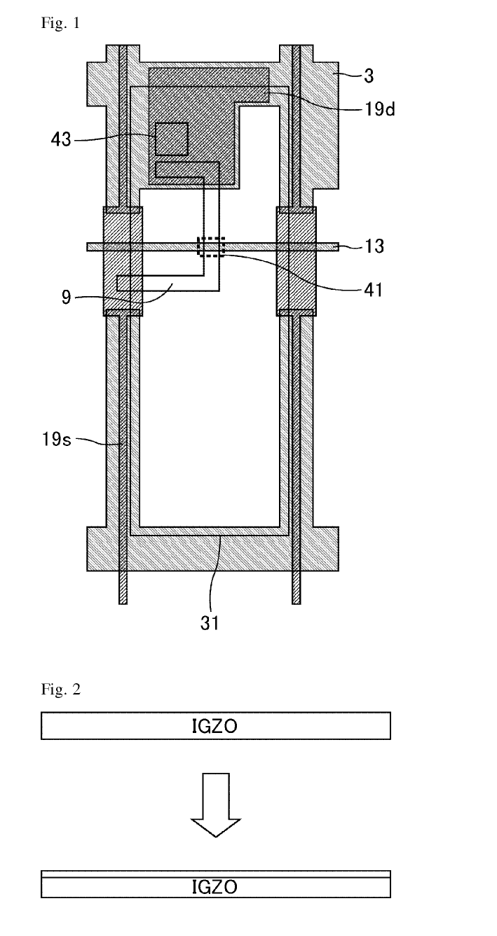

FIG. 1 is a schematic plan view to illustrate a picture element in a circuit board according to an embodiment.

In FIG. 1, an ES pattern (island pattern) 41 is formed at a portion where IGZO and a gate wire line 13 overlap each other. The IGZO at the portion where the ES pattern 41 is arranged is not yet converted into a conductive form, and thus, is in a semiconductor state. In this text, the portion where the ES pattern (island pattern) 41 is arranged as a principal surface of the board is seen in a plan view is also called a semiconductor element portion (TFT portion). In addition, as illustrated in FIG. 1 and the like, the circuit board according to the embodiment has a structure where a drain 19d formed of a source metal and a gate wire line do not overlap each other in a thin film transistor element portion as the principal surface of the board is seen in a plan view. Furthermore, the circuit board according to the embodiment has a structure where TFTs are formed at the intersection of lines of an oxide semiconductor, that is, an IGZO portion 9, of which a portion of the surface is converted into a conductive form, and the gate wire lines 13. In this structure, the area (Cgd capacitance) of the portion where the line of IGZO and the gate wire line 13 overlap each other can be configured not to vary depending on the alignment (Cgd alignment-free). In addition, a Cs wire line and a Cs 3 are formed.

Examples of the oxide semiconductor layer 17 which may be suitably used include, besides the IGZO, ISZO (In—Si—Zn—O), IAZO (In—Al—Zn—O), INiZO (In—Ni—Zn—O), ICuZO (In—Cu—Zn—O), IHfZO (In—Hf—Zn—O), and IZO (In—Zn—O). The oxide semiconductor layer 17 may be configured such that the thickness thereof is, for example, in a range of 20 nm to 300 nm.

In the embodiment, the TFT can be reduced in size, and the BM (black matrix) for light shielding can also be reduced. As a result, it is possible to increase the aperture ratio (transmittance).

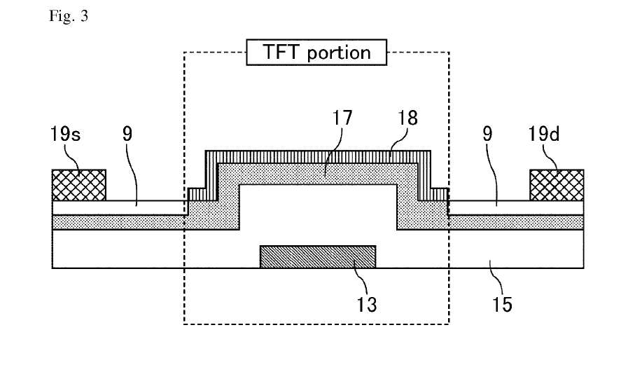

FIG. 2 is a view to illustrate a process of conversion into a conductive form according to the embodiment.

In FIG. 2, IGZO (indium-gallium-zinc complex oxide) is illustrated as the oxide semiconductor. A surface portion of the oxide semiconductor layer is subject to plasma treatment, so that the surface portion has properties of a conductor. The plasma treatment may be performed, for example, by using CF₄+O₂, HCl, HCl+O₂, SF₆+O₂, N₂, O₂, H₂, CH₄, or NH₃ gas. Due to this technique, electrical connection (source→TFT→drain→electrode of a picture element) can be formed by using only the oxide semiconductor such as a semitransparent IGZO, thereby enabling to produce TFTs having improved transmittance and merit in design (it is possible to achieve a Cgd alignment-free form by forming Cgd in the portions where the lines of the oxide semiconductor layer and the gate wire lines overlap each other). Thermal treatment or the like may be used instead of the plasma treatment.

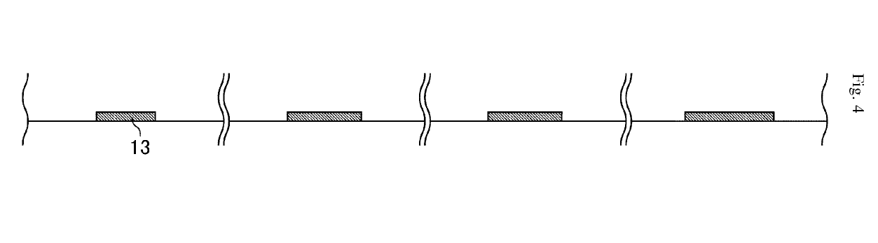

FIG. 3 is a schematic cross-sectional view of a TFT portion in the circuit board according to the embodiment.

FIG. 3 illustrates electric connection of the TFT portion. In the embodiment, the TFT is established by forming a portion (ES-pattern absence portion), which is to be converted into a conductive form, on the surface portion of the oxide semiconductor by the ES 18, and a portion (ES-pattern presence portion) which is kept unconverted. A source wire line 19s is allowed to be electrically connected to the conductive IGZO portion 9, and the TFT is switched by the ES-pattern presence portion (IGZO portion of semiconductor), so that the conductive IGZO portion 9 is connected to the drain 19d (source constituting a pair together with gate of Cs) formed of a source metal.

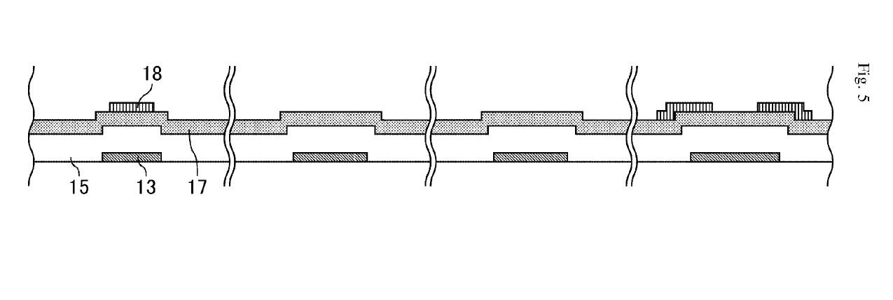

Hereafter, a method of producing the circuit board according to the embodiment will be described with reference to FIGS. 4 to 9. In the TFT illustrated in FIG. 3, as the principal surface of the board is seen in a plan view, the ES 18 is arranged so as to overlap with the entire portion of the gate wire line 13. On the contrary, in the TFT obtained in the producing method illustrated in FIGS. 4 to 9, the ES 18 is arranged so as to overlap with a portion of the gate wire line 13. Either one of the above configurations of the ES arrangement is employable.

FIG. 4 is a schematic cross-sectional view to illustrate a board where gate wire lines are formed in a method of producing the circuit board according to the embodiment. The figure illustrates a TFT portion, a storage capacitance (Cs) portion, a gate-source connection portion, and a terminal portion in this order from the left side thereof. The gate wire line 13 is formed in each of the TFT portion, the storage capacitance (Cs) portion, the gate-source connection portion, and the terminal portion. As the gate wire line layer, a generally-used layer may be used. For example, the gate wire line may be formed as a single layer of an aluminum alloy.

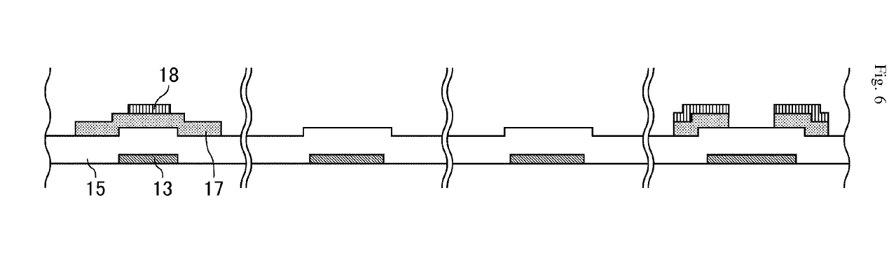

FIG. 5 is a schematic cross-sectional view to illustrate the board obtained through a process that includes the steps of forming an oxide semiconductor layer, arranging ES (etching stopper), and performing plasma treatment on the oxide semiconductor layer (converting process) in the method of producing the circuit board according to the embodiment. On the board illustrated in FIG. 4, an insulating film 15 and an oxide semiconductor layer 17 are further formed, and the ES 18 is arranged in the TFT portion and the terminal portion. This process is a process for electrically separating the source from the drain via the insulating film of the ES, which is used before the introduction of a process for separating the source from the drain by channel etching. In this process, the ES is maintained, so that the IGZO under the ES is not converted into a conductive form but maintains a property of semiconductor and the portion where the ES is absent is converted. In other words, in the conversion, the IGZO is converted into a conductive form through plasma treatment or the like. Thus, if the ES is present, the plasma does not reach the portion, the portion is not converted. A preferred mode of the conversion treatment into a conductive form, such as plasma treatment, is the same as described above with reference to FIG. 2.

FIG. 6 is a schematic cross-sectional view to illustrate the board obtained through etching on the oxide semiconductor layer 17 in the method of producing the circuit board according to the embodiment.

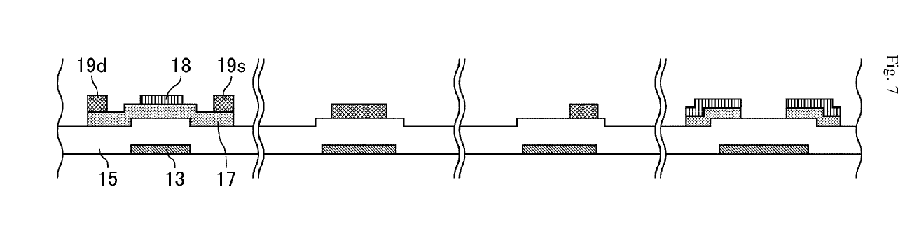

FIG. 7 is a schematic cross-sectional view to illustrate the board obtained through formation of the source wire line 19s and the drain 19d formed by using a source metal in the method of producing the circuit board according to the embodiment. A conductive layer is further formed on the board illustrated in FIG. 6. Next, resist is formed by a mask process, and the wire line layer is etched, to give the source wire lines 19s and the drains 19d formed of a source metal. Next, the resist is removed from the board. The source wire line 19s and the drain 19d formed of a source metal are disposed at positions separated away from the gate wire line 13, so that it is possible to reduce the Cgd, to achieve alignment-free of the gate and source, and to achieve an alignment-free form of the gate and drain. For example, as the principal surface of the board is seen in a plan view, the drain 19d formed by using a source metal and the gate wire line 13 are configured so as not to overlap each other, so that it is possible to substantially achieve an Cgd alignment-free form, to reduce the area of the Cs, and to increase the aperture ratio. As the source wire line 19s and the drain 19d formed by using a source metal, a generally-used material may be used. For example, an Al alloy/Ti may be used.

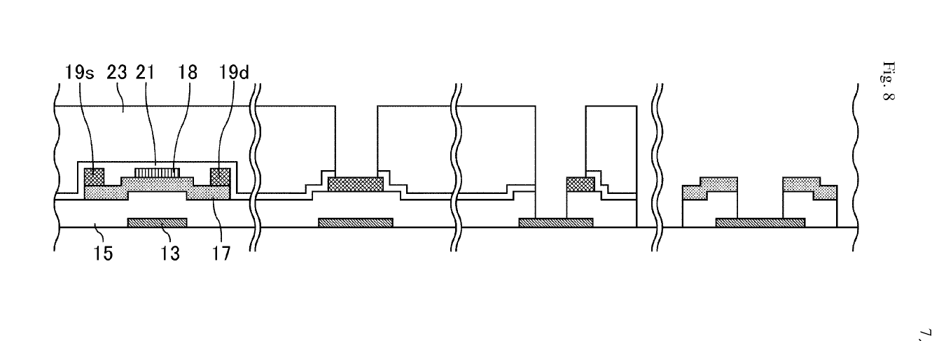

FIG. 8 is a schematic cross-sectional view to illustrate the board where an organic insulating film 23 is formed in the method of producing the circuit board according to the embodiment. An insulating film 21 is further formed on the board of the resulting product of FIG. 7, the organic insulating film 23 is formed thereon, and contact holes are formed in the storage capacitance (Cs) portion, the gate-source connection portion, and the terminal portion through etching.

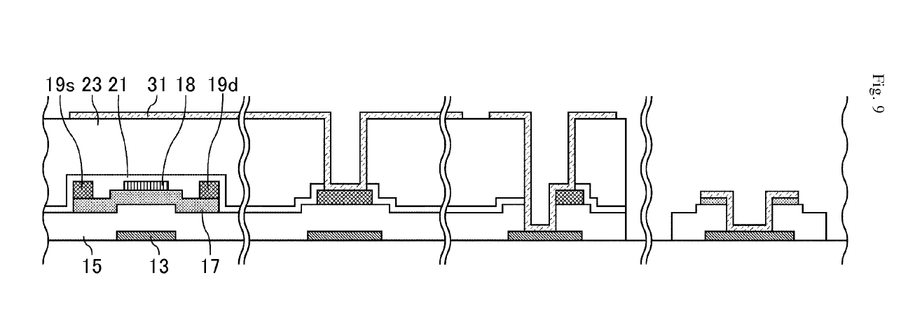

FIG. 9 is a schematic cross-sectional view to illustrate the board where an electrode of a picture element 31 is formed in the method of producing the circuit board according to the embodiment. The electrode of a picture element 31 is further formed on the resulting product of FIG. 8. Accordingly, a circuit board having an excellent aperture ratio can be appropriately produced through a mask process using six masks. In the embodiment, the TFT is established by forming an IGZO portion (ES-pattern absence portion), which is converted into a conductive form, on the surface of the oxide semiconductor by the ES 18 and an IGZO portion (ES-pattern presence portion, the oxide semiconductor 17) which is not converted. A conductor portion is allowed to be electrically connected from the source wire line 19s through the converted IGZO portion 9 to the ES absence portion of the gate, the TFT is switched by the ES-pattern presence portion (IGZO portion of semiconductor) on the gate, and the conductive drain (conductive IGZO portion) is allowed to be connected to the drain 19d formed by using a source metal (source constituting a pair together with gate of Cs).

In comparison with a currently-used a-Si TFT, it is possible to increase the aperture ratio (transmittance) according to decrease of the TFT area and the TFT shielding area. In the embodiment, since the oxide semiconductor layer has high mobility, the TFT area (semiconductor area) can be reduced, so that it is possible to increase the aperture ratio. In addition, in the embodiment, the source and the drain can be sufficiently electrically connected to each other by using only the oxide semiconductor, so that it is possible to obtain merit in design (Cgd alignment-free), to reduce the area of Cs, and to increase the aperture ratio. In addition, the TFT is not shielded by the BM, so that it is possible to increase the aperture ratio. Compared with a high-definition liquid crystal display (200 dpi or more) which is produced with low-temperature polysilicon TFTs by using about ten masks, the equivalent aperture ratio can be obtained by using six masks in the producing method according to the embodiment, so that it is possible to obtain merit in costs.

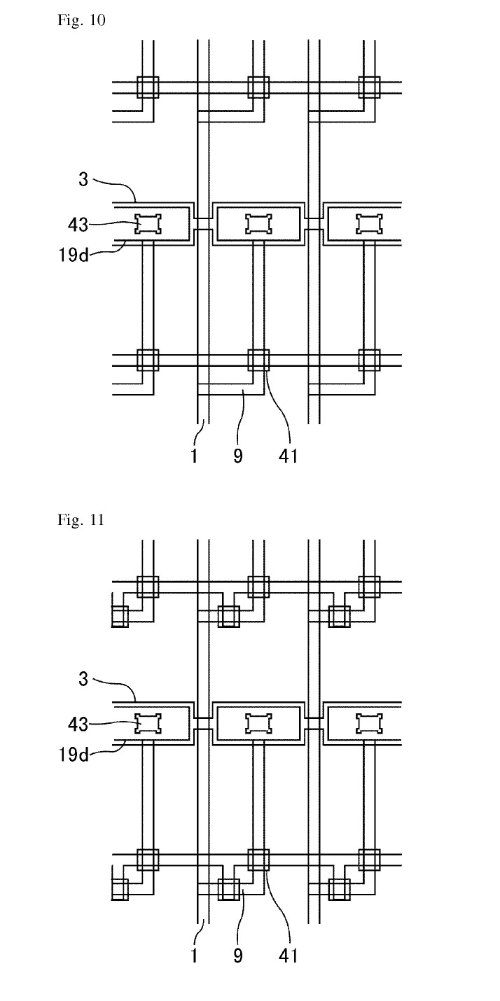

FIG. 10 is a schematic plan view to illustrate picture elements in a circuit board that includes one TFT per picture element as a modified example of the embodiment. In this embodiment, the same effect as mentioned above can be obtained in increasing the aperture ratio.

FIG. 11 is a schematic plan view to illustrate picture elements in a circuit board that includes two TFTs per picture element as a modified example of the embodiment. Two TFTs are arranged in serious, so that OFF resistance of the TFT is reduced, and thus, a BM-free configuration can be achieved.

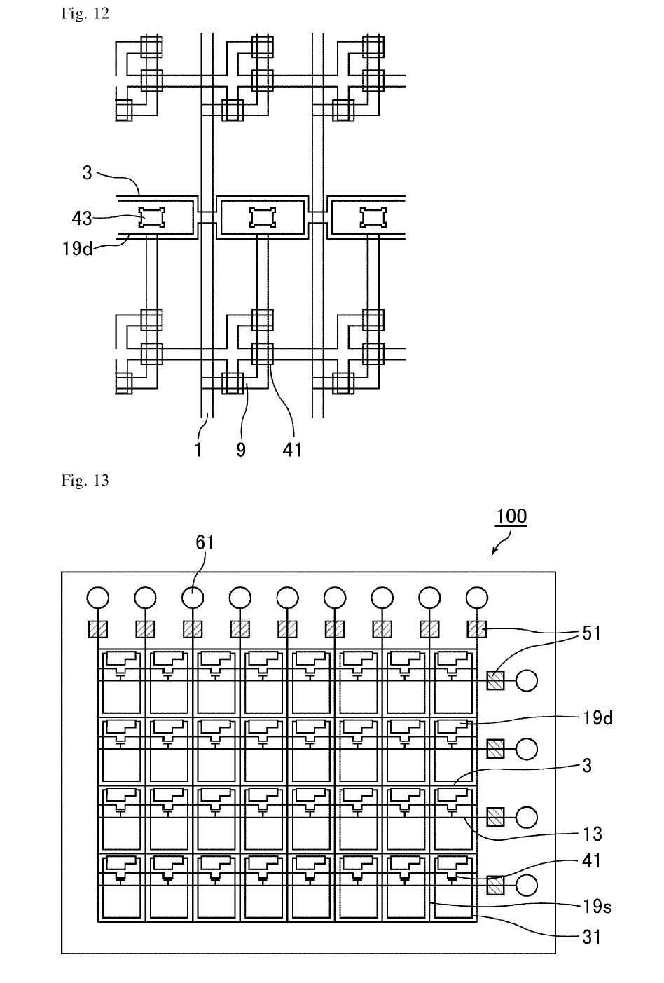

FIG. 12 is a schematic plan view to illustrate picture elements in a circuit board that includes three TFTs per picture element as a modified example of the embodiment. Three TFTs are arranged in serious, so that the OFF resistance of the TFT is further reduced, and thus, a BM-free configuration can be achieved.

FIG. 13 is a schematic plan view to illustrate the circuit board according to the embodiment.

The circuit board 100 is a TFT-side board where thin film transistors (TFTs) are installed. The board includes an area of an electrode of a picture element (display area) and an area (non-display area) outside the area of an electrode of a picture element.

A connection portion 51 and a terminal portion 61 are disposed in the non-display area. A source driver can be mounted through the connection portion 51 on the circuit board 100, for example, in a chip-on-glass (COG) manner. A flexible printed circuit (FPC) can be mounted through the terminal portion 61 on the circuit board 100. For example, signals for driving the source driver can be input from the FPC through the terminal portions 61 and 51.

In the display area of the circuit board 100, the gate wire lines 13 and the source wire lines 19s are disposed on a glass substrate (not illustrated) so as to be substantially perpendicular to each other, and the electrodes of picture elements 31 and the TFTs are installed in the areas surrounded by the gate wire lines 13 and the source wire lines 19s. The drains 19d formed of a source metal are disposed so as to overlap with the electrodes of picture elements 31.

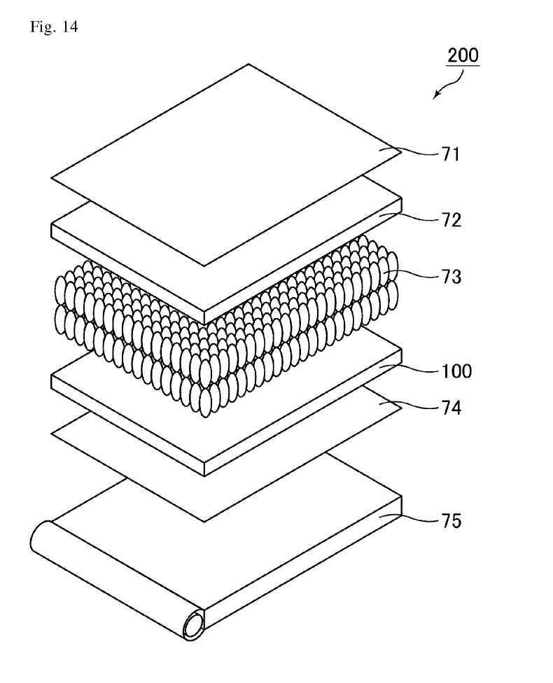

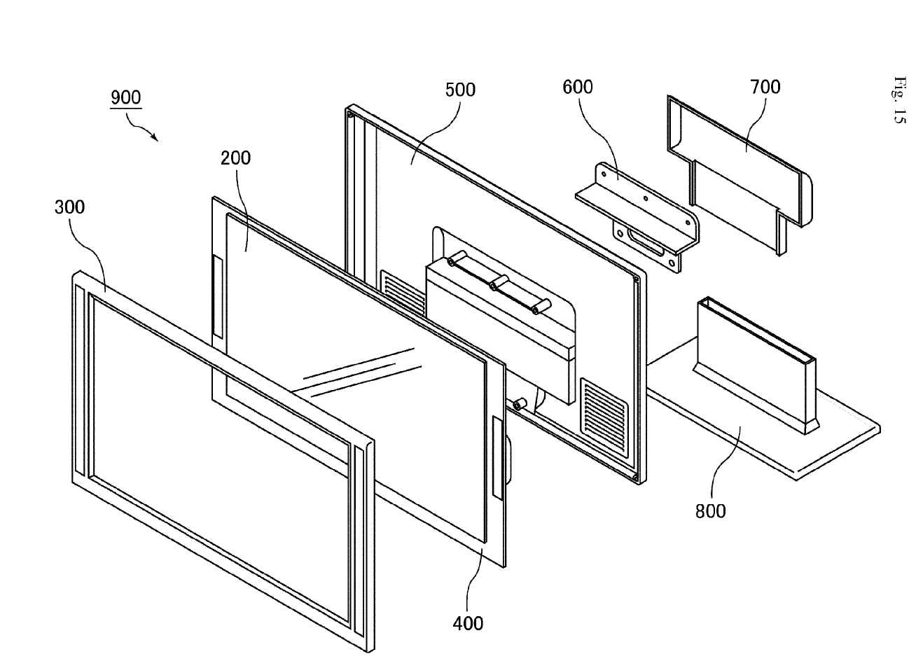

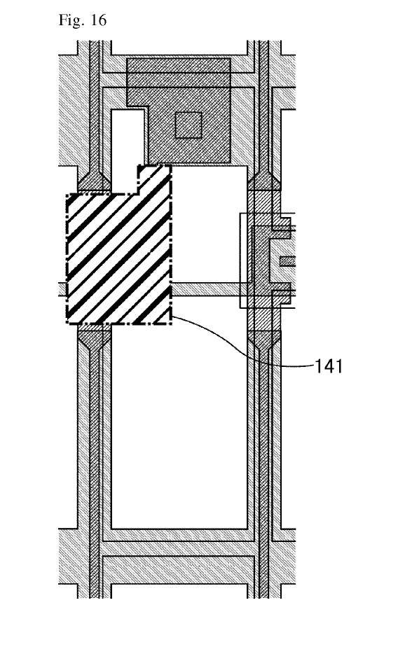

FIG. 14 is a schematic exploded perspective view to illustrate a structure of a liquid crystal panel according to the embodiment. FIG. 14 illustrates the structure of the liquid crystal panel that includes the circuit board according to the first embodiment. As illustrated in FIG. 14, liquid crystals 73 are interposed between a CF-side board 72 and the circuit board 100 of the liquid crystal panel 200. The liquid crystal panel 200 is configured such that a backlight 113 is disposed on a rear surface of the circuit board 100. The light of the backlight 113 passes through a polarizing plate 74, the circuit board 100, the liquid crystals 73, the CF-side board 72, and a polarizing plate 71 in this order, and transmitting and shielding of light is controlled through control of orientation of the liquid crystals. In the embodiment, due to the optical property of the IGZO, the TFT may not be shielded by the BM, so that it is possible to increase the aperture ratio.

FIG. 15 is a schematic exploded perspective view to illustrate a structure of a liquid crystal display device that includes the liquid crystal panel illustrated in FIG. 14. As illustrated FIG. 14, the liquid crystal panel 200 is fixed on a fixing panel 400 and is sealed with a front cabinet 300 and a rear cabinet 500. Next, the rear cabinet 500 is fixed to an upper stand 700 through metal fittings 600. Then, the upper stand 700 is fitted into a lower stand 800.

Although FIGS. 14 and 15 illustrate a configuration of a liquid crystal display device, the display device according to the present invention is not limited thereto, but the same functions and effects can be obtained by an EL display device such as an organic EL display device or an inorganic EL display device.

The aforementioned modes of the embodiments may be employed in appropriate combination as long as the combination is not beyond the spirit of the present invention.

The present application claims priority to Patent Application No. 2010-037554 filed in Japan on 23 Feb. 2010 under the Paris Convention and provisions of national law in a designated State, the entire contents of which are hereby incorporated by reference.

### REFERENCE SIGNS LIST

3: Cs wire line and Cs
9: IGZO portion which is converted into a conductive form
13: Gate wire line
15, 21: Insulating film
17: Oxide semiconductor layer
18: ES
19s: Source wire line
19d: Drain formed of source metal (one source constituting a pair together with gate of Cs)
23: Organic insulating film
31: Electrode of a picture element
41: ES pattern (island pattern)
141: TFT
43: Source-picture element electrode connection portion
51: Connection portion
61: Terminal portion
71, 74: Polarizing plate
72: CF-side board
73: Liquid crystal
75: Backlight
100: Circuit board
200: Liquid crystal panel
300: Front cabinet
400: Fixing panel
500: Rear cabinet
600: Metal fittings
700: Upper stand
800: Lower stand
900: Liquid crystal display device

1. A method of producing a circuit board that carries a thin film transistor, the thin film transistor including an oxide semiconductor layer,
the method comprising steps of:
forming the oxide semiconductor layer; and
converting the oxide semiconductor layer into a conductive form.

2. A circuit board obtainable by the method of producing the circuit board according to claim 1.

3. A circuit board that carries a thin film transistor, the thin film transistor including an oxide semiconductor layer,
wherein the oxide semiconductor layer includes a portion of which the surface is converted into a conductive form and a portion of a semiconductor layer.

4. The circuit board according to claim 2,
wherein the oxide semiconductor layer is formed of an indium-gallium-zinc complex oxide.

5. The circuit board according to claim 2,
wherein the circuit board is configured so that a lower layer of the oxide semiconductor layer is formed of an insulating film, and
an upper layer of a conductive portion of the oxide semiconductor layer is configured with an insulating film.

6. The circuit board according to claim 2,
wherein the circuit board is configured so that a drain formed of a source metal and a gate wire line do not overlap each other in a thin film transistor element portion as the principal surface of the board is seen in a plan view.

7. The circuit board according to claim 2,
wherein the oxide semiconductor layer includes a portion of which the resistivity is equal to or higher than 10² μΩ·cm but equal to or lower than 10⁸ μΩ·cm.

8. The circuit board according to claim 7,
wherein the oxide semiconductor layer further includes a portion of which the resistivity is higher than 10⁸ μΩ·cm.

9. The circuit board according to claim 2,
wherein the circuit board comprises two or more thin film transistor elements that are disposed in series per electrode of a picture element.

10. The circuit board according to claim 2,
wherein the circuit board includes a portion where the thin film transistor element and a light-shielding layer do not overlap each other as the principal surface of the board is seen in a plan view.

11. A display device comprising the circuit board according to claim 2.
